(19) United States
(12) Patent Application Publication
(10) Pub. No.: US 2004/0207422 A1
(43) Pub. Date: Oct. 21, 2004

(54) Aligning and testing system for communication device manufacturing

(75) Inventors: Kari Tapani Lehtinen, Salo (FI); Jari Muurinen, Pernio (FI)

Correspondence Address: WARE FRESSOLA VAN DER SLUYS &, ADOLPHSON, LLP, BRADFORD GREEN BUILDING 5, 755 MAIN STREET, P O BOX 224, MONROE, CT, 06468, US

(73) Assignee: Nokia Corporation

(21) Appl. No.: 10/412,756

(22) Filed: Apr. 11, 2003

(51) Int. Cl. G01R 31/02

(52) U.S. Cl. 324/758

(57) ABSTRACT

A system and method for aligning and testing a communication device during production speeds up the overall production testing and thus shortens the testing time. The system comprises a measuring unit, RF switch, power supply and test bed comprising several modular test places, and is synchronized to perform test procedures with a minimum amount of control information transfer between the device under test and the test system. This is achieved by using low level and real time control operations, and configuring the test hardware to be only a little bit better and a little bit faster than the device under test itself.

### TECHNICAL FIELD OF THE INVENTION

The present invention generally relates to the manufacturing of communication devices, and more particularly, the present invention provides a new method and system for aligning and testing during manufacturing communication devices.

### BACKGROUND OF THE INVENTION

To align and test an electronic communication device during manufacturing is rather complicated, time-consuming and expensive procedure at the moment. Today's production aligning and testing systems typically comprise several parallel testing stations per production line to meet the capacity requirements of manufacturing of communication devices. General purpose or multifunctional instruments are used to meet production test requirements, despite the fact that only part of their functionality is exploited.

During manufacturing a lot of alignments and tests are performed for an electronic communication device such as a mobile phone. These include e.g. battery management calibrations, receiver and transmitter calibrations, and tests to check that a radio frequency (RF) part and a baseband (BB) part of the mobile phone meets all the required specifications and is working properly. To fulfil all alignment and test items high performance multifunctional testing and measuring instruments are today employed in the production line. In case of a multiband mobile phone operating in different frequency bands at least substantial parts of test procedures must be repeated in each frequency band of operation.

The production alignment and testing presumes tight control of testing procedures and management of test results. The main component of today's production aligning and testing systems is a control PC unit which has a full control over the whole test procedure. This means that production alignments and tests are based on a continuous communication between a mobile phone engine module and a control PC unit of a test system. In connection with control PC units the test software is generally configured on top of the high level application software to run in real-time but contemporaneously operating systems used in PCs, e.g. Windows, are not operating sufficient real-time. In consequence of the PC unit centric production testing there is remarkable information transfer between the control PC unit and the mobile phone unit under test. In addition the PC unit has to control several testing stations and measurement instruments therein nearly simultaneously which may induce the control system quite easily to be unstable and sensitive to many kinds of interferences.

Test instruments employed in production alignment and test are today rather complicated because dedicated instrumentation has not been developed. Communication systems are also getting more complicated which means that the development work of testing algorithms has to go on all the time as well as a need to increase the speed of testing operation is continuously growing. Thus the instrumentation is getting rather expensive which increases testing costs. On the other hand due to the complexity of testing systems the test times are increasing. In consequence of these elongated test times there may develop bottlenecks to the production line.

Problems may occur especially, when research and development work of the mobile phone is at the beginning and the mobile phone software is not yet mature. In this case, it is often impossible to get the production test system up and running which then delays the electronics verification procedure, especially RF verification. This kind of situation may occur e.g. when the electronics of a communication device are ready for statistical improvements long before reliable results from production tests are available. This makes more difficult or even impossible to take measures to improve long term yield properties according to the reliable test results in the early stage of the production start-up and it means that actions to improve yield have to be left close to the ramp-up phase of the production.

The use of high performance general purpose and/or multifunctional testing and measuring instruments together with the need of several parallel test stations per production line add to the cost of production aligning and testing systems. A set-up of parallel test stations per production line also uses quite a large surface of floor area in production facilities. The complexity of production testing systems and a massive information transfer between the control PC unit and device under test make test times longer and thereby cause difficulties to meet the production capacity targets. The present invention aims to address the above problems.

### SUMMARY OF THE INVENTION

An objective of the invention is to solve the problems related to prior art and thus provide a method and system for aligning and testing a communication device during manufacturing to speed up the overall production testing and to shorten the overall production testing time.

The objective of the invention is fulfilled by providing a method and system where at least part of test procedures are performed by the communication device itself and the data communication between a communication device and a control unit of a measuring equipment is minimized.

In this description the test procedure comprises alignment and test sequences, which are called here simply test sequences, to perform communication device alignments with associated measurements and tests.

In accordance with the invention there is provided a method for aligning and testing during manufacturing at least one communication device operable in at least one frequency band by running a test procedure which is programmed in a memory of the communication device and in a memory of a control unit of a measurement unit, said test procedure comprising aligning and testing operations, the method comprising the steps of executing at least part of the test procedure by the communication device itself and minimizing information transfer between the control unit of the measuring device and the communication device during the test procedure.

In accordance with the invention there is provided a system for aligning and testing during manufacturing at least one communication device operable in at least one frequency band arranged to run a test procedure which is programmed in a memory of the communication device and in a memory of a control unit of a measurement unit, said test procedure comprising aligning and testing operations, the system comprising means for executing at least part of the test procedure by the communication device itself and means for minimizing information transfer between the control unit of the measuring device and the communication device during the test procedure.

In accordance with the invention there is provided an interface for aligning and testing during manufacturing at least one communication device operable in at least one frequency band to co-operate with an operating system of the communication device, by running a test procedure which is programmed in a memory of the communication device and in a memory of a controller of a measuring unit, said test procedure comprising aligning and testing operations, and said operating system comprising system operations, the interface comprising computer program code for executing at least part of the test procedure by the communication device itself and for minimizing information transfer between the control unit of the measuring unit and the communication device during the test procedure.

The invention provides a method and system to speed up a testing time in production alignment and test to the limit which only depends on the speed the communication device is operating itself. In addition, due to this shorter testing time fewer number of parallel test stations are needed and thereby cost savings of instrumentation investments are achieved. The method and system according to the invention can be implemented in any factory, production facility and production line in pursuance of saving floor area.

In addition, the invention provides a simplified interface for test procedures to cooperate with an operating system of the communication device when aligning and testing the communication device during manufacturing.

Some embodiments of the invention are described in the dependent claims.

The novel features which are considered as characteristics of the invention are set forth in particular in the appended Claims. The invention itself, however, both as to its construction and its method of operation, together with additional objects and advantages thereof, will be best understood from the following description of specific embodiments when read in connection with the accompanying drawings.

BRIEF DESCRIPTION OF THE DRAWINGS

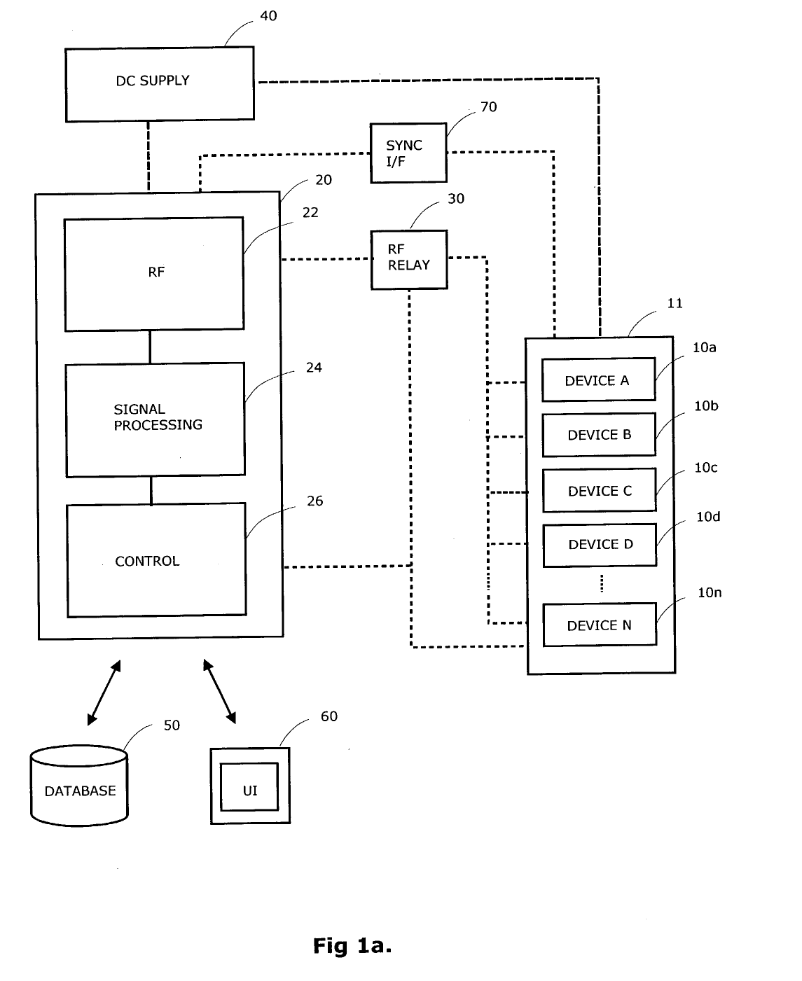

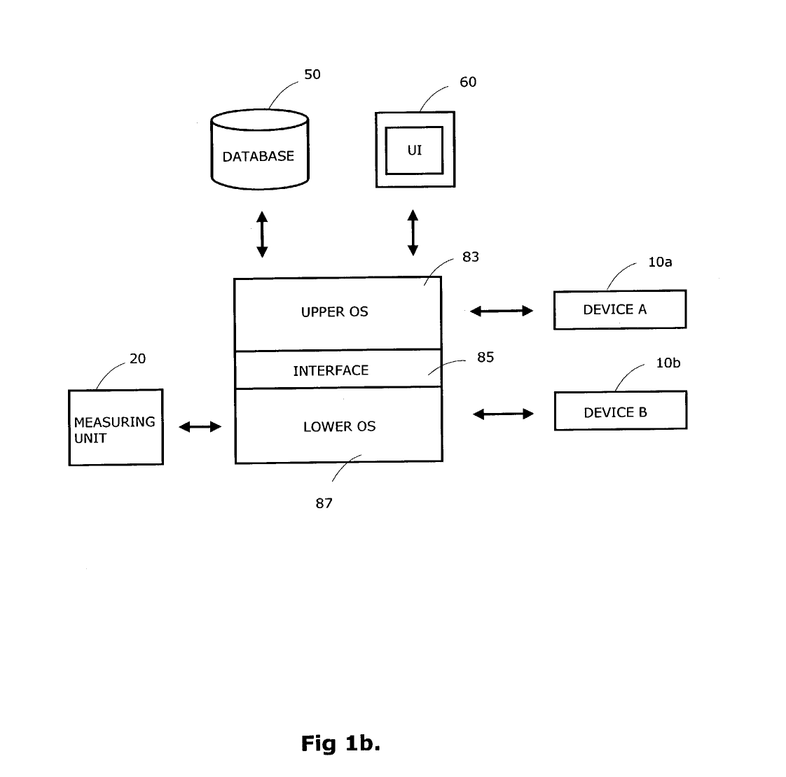

FIG. 1a illustrates a block diagram of an embodiment of a system for aligning and testing an electronic device during manufacturing according to the invention.

FIG. 1b illustrates a block diagram of a simplified interface for aligning and testing an electronic device during manufacturing according to the invention.

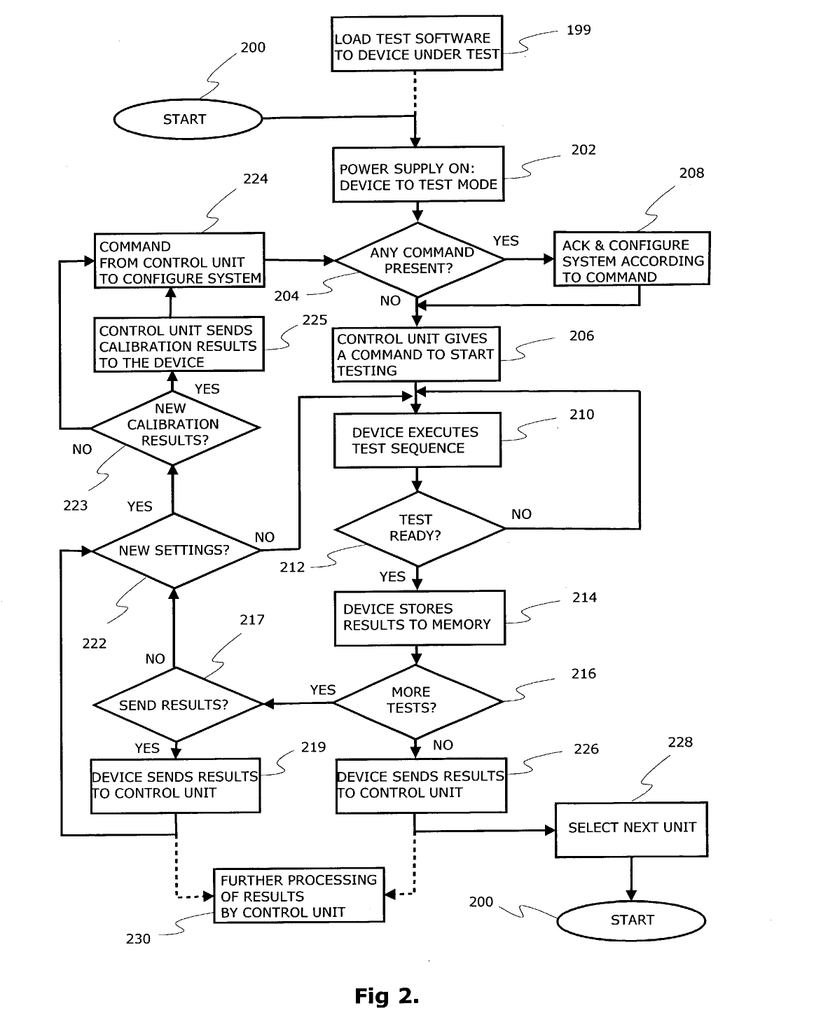

FIG. 2 illustrates a flow diagram of one embodiment of a method for aligning and testing an electronic device during manufacturing according to the invention.

### DETAILED DESCRIPTION

Today, production test systems of communication devices, such as mobile phones, use rather complicated and expensive instrumentation compared to the operations required to perform production aligning and testing. In last couple of years there has been a trend that the instrumentation is becoming less complicated but still there are high performance multifunctional instruments used to perform rather limited set of operations in production lines.

According to the invention a method and system is provided where at least part of test procedures are performed by the communication device itself and the data communication between a communication device and a control unit of a measuring equipment is minimized. This is achieved by using low level and real time control operations as well as dedicated instrumentation instead of general purpose devices.

In this description as an example of a communication device is represented a mobile phone which is preferably a GSM (Global System for Mobile communications) phone, WCDMA (Wideband Code Division Multiple Access) phone or a mobile phone compatible to any other enhanced evolution of GSM. A mobile phone is capable of a single, dual or multiband operation. The communication device comprises at least a transmitter for sending messages and a receiver for receiving messages, a controller for processing data and a memory for storing data.

Many of the routines inside the mobile phone are independent and they are executed automatically without any need for measures to be taken by an external control device. As an example of this type of automated routine is an RSSI (Received Signal Strength Indicator) alignment which is a digital signal processing (DSP) routine controlled by the mobile phone. The RSSI is a measure of RF signal strength at input when a DC signal is in intermediate frequency (IF) amplification stage. When the mobile phone is switched on it starts a complicated sequence of operations and as a result of operations the phone is recognized by a base station of a mobile network to be ready to send and receive call commands. This sequence of operations includes RF level measurements, synchronization, information decoding, authentication, etc. Individual operations are often executed at a frame or multiframe basis which means that they are very fast and accurate operations.

The above-mentioned operations which the mobile phone itself automatically executes when switched on are usually more complicated than the operations required to perform production alignments and tests, because the latter only require the carrying out of a limited number of measurements and to report those measurement results.

This indicates that most of the alignments can be made according to the same principle as the routines inside the mobile phone are performed. As measurement equipment the mobile phone performs many operations with good speed and accuracy. For example, the mobile phone is able to measure RF signal strength, frequency error, DC level, signal-to-noise ratio and other similar measurements. To calibrate such a mobile phone there is a demand on instrumentation to be only a little bit more accurate, a little bit faster and to have a little bit lower noise that the mobile phone itself. E.g. a typical accuracy rate of the mobile phone is in order of magnitude ±2 decibels for power levels and 0.1 ppm for frequencies. According to the invention the speed of the measuring unit 20 is optimized to the speed of the mobile phone under test so that the speed of the measuring unit does not limit the overall testing time.

In this description the test procedure comprises alignment and test sequences, which are called here simply test sequences, to perform mobile phone alignments with associated measurements and tests. The test sequences are divided into sub-sequences where each sub-sequence is long enough to minimize the communication between the measuring unit and the device under test and short enough to maintain sufficient error checking capabilities. The test procedure of the mobile phone under test is also optimized to the speed and timing requirements of the measuring device. The sequential order of test sequences can be altered for practical reasons.

FIG. 1a shows a block diagram of the production aligning and testing system according to an embodiment of the invention. In the following the expression test system relates to the production aligning and testing system. A test system according to one embodiment of the invention comprises a test bed 11, measuring unit 20, switch 30 and power supply 40. The measuring unit 20 comprises a RF part 22, signal processing part 24 and control unit 26 which controls the operation of the measuring unit and power supply. The test bed 11 consists of several parallel modular test places (not shown) for a communication device, such as a mobile phone, 10a, 10b, . . . , 10n to be tested. Each modular test place is connectable to a control path for communication, a RF path for RF connection and a power supply path for DC supply connection via relevant interfaces, such as connectors. In addition, there is a synchronization interface 70 between the test bed 11 and measuring unit 20. It is needed in the cases where a very fast communication is needed between the device under test 10a, 10b, . . . , 10n and the control unit 26.

The control unit 26 selects a device 10a, 10b, . . . , 10n to be tested by switching on the connection from the power supply 40 to the relevant device, e.g. a mobile phone 10a, to be switched on. When the mobile phone is switched on to the normal operation mode it starts a sequence of operations including RF level measurements, synchronization, information decoding, authentication, etc. When the mobile phone is switched on to the test mode it remains in the wait state until it receives a command to start testing. Next the control unit gives a command to start testing via the control path to the same device 10a. In other words the mobile phone under test is activated by switching DC supply on and receiving a command from the control unit 26. When RF operation of the mobile phone is tested or needed in a test, a RF path must be opened to the corresponding mobile phone 10a by a RF relay 30 which is a switch controlled by the control unit 26. In case a test sequence does not need any external signals, it is not necessary to open the corresponding RF path to start this test sequence.

The RF part 22 of the measuring unit 20 must be capable of handling all the frequency bands of operation needed in a flexible way and having an accurately transmitted power level, an accurate receiver gain and a stable frequency reference. All these features are also required from the mobile phone and at the block diagram level the RF part can be similar to the mobile phone itself. The key issues concerning the RF part 22 are calibration capability and reliable operation. The signal processing part 24 of the measuring unit 20 comprises at least a waveform memory, D/A converter, A/D converter and sample memory. The waveform memory comprises all the required waveforms which are needed in the mobile phone receiver (RX) alignment and test, e.g. waveforms for Gaussian Minimum Shift Keying (GMSK), 8-Phase Shift Keying (8-PSK) and Amplitude Modulation (AM). The D/A converter block converts digital waveforms to analog ones and performs the required anti-aliasing and noise filtering. The A/D converter block converts analog waveforms transmitted by the mobile phone transmitter (TX) to digital samples which are then stored to the sample memory for further processing. The control unit 26 of the measuring unit 20 comprises at least a processor unit and a control logic which together perform in real-time the required switching and timing operations for the RF part 22 and signal processing part 24, and in addition the control unit is connected to a Personal Computer (PC) which handles the communication to databases and user interfaces (UI). Thus, the control unit 26 acts as an interface to the database 50 and user interface 60 so that all the results from test procedures of the mobile phone are stored to the database and displayed/printed by the user interface in a proper way. Since the communication to the database and user interface is controlled by the PC, in consequence the full capacity of the processor of the control unit of the measuring unit is released for controlling the mobile phone and processing the measurement results.

As shown in FIG. 1b, according to the invention a simplified interface 85 for test procedures of the mobile phone is provided to co-operate with an operating system of the mobile phone, when aligning and testing the device during manufacturing. This interface is part of the test procedure synchronized with the alignment and test system, i.e. optimized to the speed and timing requirements of the measuring unit 20. This interface facilitates the communication between the upper level operating system 83 and lower level operating system 87. The lower level operating system controls the communication between the measuring unit and the mobile phone under test, while the upper level operating system stores the measurement results to the database and executes possible user interface operations e.g. displaying the results via user interface. The operations controlled by the upper level operating systems are enacted in parallel with the operations of the lower level operating system for the previous device under test. This means that, as shown in FIG. 1b, when the measurement results of the device A 10a are further processed e.g. stored to the database 50, at the same time the test procedure for the device B 10b is performed, etc.

FIG. 2 shows a flow chart of the production aligning and testing method according to an embodiment of the invention. Let's presume that a test software comprising a test procedure is already programmed to the memory of the mobile phone under test as depicted in step 199 before the alignment and test procedure starts. The test software is preferably programmed to a flash memory of the mobile phone. The test procedure includes alignment and test sequences, which are called here just test sequences, to perform mobile phone alignments with associated measurements and tests. The sequential order of these test sequences can be altered by practical reasons, so the description below should be mainly taken as an example.

According to one embodiment of the invention test software comprising a test procedure is part of a whole mobile phone software which mobile phone software is programmed to the memory of the mobile phone before the alignment and test procedure starts. According to another embodiment of the invention a test software comprising a test procedure is a software block which is an independent part of the mobile phone software, and the test software block is programmed to the memory of the mobile phone before the alignment and test procedure starts. An advantage of the latter embodiment is that the production alignment and test can be started although the rest of the mobile phone software is still under development process. Then the rest of the mobile software is programmed in the later stage to the memory of the mobile phone. According to this latter embodiment of the invention the test software comprising the test procedure can be erased from the memory of the mobile phone after the whole test procedure is completed and thus makes available free memory space for other purposes.

As shown in FIG. 2, in the beginning 200 of the test procedure of the communication device, such as the mobile phone, the device under test is activated by supplying DC power to the device and the device is then switched on to the test mode according to step 202. Next in step 204, the device under test listens if there are any commands sent from the control unit of the measuring unit to change settings such as frequency, power level or operation voltage. Steps 204 and 208 ensure that the device under test and the measuring unit have the same settings during test procedure. If there are no new commands coming it means that the settings remain the same as before and the test procedure starts when the control unit of the measuring unit gives a command according to step 206. If changes to settings occur in step 204 the mobile phone sends an acknowledgement to the control unit of the measuring unit which then configures the mobile phone and the measuring unit with new settings according to the command in step 208. The test procedure starts when the control unit of the measuring unit gives a command according to step 206 and after sending this command the control unit of the measuring unit is switched to the listen mode. Then in step 210 the device under test itself executes a test sequence, which is a part of the test procedure, without any communication of the control unit of the measurement unit during the test procedure until new settings for measurements are required. When this test sequence is completed in step 212, the device under test stores the results to its permanent memory in step 214. If there are more tests to be performed in step 216, and if there are no new instructions from the control unit available to the device under test in step 222, the device under test continues testing without any need for communication to the control unit of the measuring unit according to steps 210-216, i.e. there is no communication traffic on the bus between the device and the control unit during that period. If the device under test wants to send the test results or part of the results to the control unit in the middle of the testing procedure, it is possible according to steps 217 and 219. If the device under test asks the control unit of the measuring unit to change any settings, it sends a corresponding message to the control unit e.g. in association with these test results it sends to the control unit, or it just sends a simple message to change settings to the control unit in step 219. The control unit of the measuring unit listens to the communication bus to the device for possible requests to change settings after step 206.

When the device under test asks the control unit of the measuring unit to change any settings by sending a message to the control unit in step 219, and/or the control unit wants to change settings, there is a need for new settings in step 222. Then in step 224 the control unit of the measuring unit generates a command to inform the device under test for changed settings in step 204, and to configure the system according to the command in step 208. In some cases the device under test may request results from the control unit of the measuring unit during the test procedure. For example alignment results from transmitter calibrations are stored into the memory of the control unit of the measuring unit. If these results are requested according to step 223 the control unit will send the values to the device in step 225 and then in step 224 the control unit of the measuring unit generates a command to inform the device under test for changed settings in step 204, and to configure the system according to the command in step 208. In some cases the device under test may request results from the control unit of the measuring unit during the test procedure. For example alignment results from transmitter calibrations are stored into the memory of the control unit of the measuring unit. If these results are requested according to step 223 the control unit will send the values to the device in step 225 and then in step 224 the control unit of the measuring unit generates a command to inform the device under test for changed settings in step 204, and to configure the system according to the command in step 208. Step 208 ensures that the settings are the same in the device under test and in the measuring unit. After this a new test sequence or a new test procedure starts when the control unit gives a command to start testing in step 206 and tests are performed according to steps 210-216.

Most of the commands to change settings and to send or receive results are given through the control interface (steps 206, 208, and 224 in FIG. 2). In some cases, however, even this optimized control interface might be too slow. Then synchronization interface (70 in FIG. 1a) might be used. Basically, this interface is a simple pulse indicating that a certain test sequence has been completed and it is time to start the next one. The synchronization is a bi-directional link, i.e. both the control unit and the device under test can send and receive through this interface.

When all the test procedures for the device under test are completed in step 216, the device under test sends the results stored to its memory (or the remaining part of the results that have not yet been sent in step 219) to the control unit of the measuring unit in step 226. According to another embodiment of the invention when at least part of the test procedure for the device under test is completed, the device sends the results stored to its memory to the control unit in step 219 and the rest of the results in step 226 when all the test procedures are completed. When receiving the message according to step 226 from the mobile phone the control unit determines that all the test procedures for the current device under test are completed and it gives a command to select a new device to be a device under test according to step 228. When receiving the results from the device under test according to steps 219 and 226, the control unit of the measuring unit stores the results to its memory for further processing. Step 230 depicts this further processing and it includes e.g. storing all the results to the database, displaying the results via user interface and other user interface operations. Performing step 230 for the current device under test and executing the test procedure for the next device under test are parallel operations according to the invention.

According to the invention a simplified interface for test procedures of the mobile phone is provided to co-operate with an operating system of the mobile phone, when aligning and testing the device during manufacturing as described in association with FIG. 1b. The lower level operating system controls the communication between the measuring unit and the mobile phone under test according to steps 224 and 226, while the upper level operating system stores the measurement results to the database and executes possible user interface operations e.g. displaying the results via user interface according to step 230. The operations controlled by the upper level operating systems are enacted in parallel with the operations of the lower level operating system for the previous device under test. This means that, as shown in FIG. 1b, when the measurement results of the device A 10a are further processed e.g. stored to the database 50, at the same time the test procedure for the device B 10b is performed, etc.

The above description of alignments and tests during production in association with FIG. 2 particularly applies for mobile phone self tests and energy management as well as receiver calibrations. It is typical for these kind of tests that the communication device, such as the mobile phone, itself makes the measurements according to steps 204 to 216 and then the mobile phone reports the measurement results according to steps 219 and/or 226.

Next an exemplary embodiment of the method for aligning and testing during manufacturing according to the invention is provided. To start with a test procedure for an energy management calibration of a GSM or WCDMA mobile phone 10a, 10b, . . . 10n during production is presented. Let's presume that a test software comprising a test procedure is programmed to the memory, preferably flash memory, of the mobile phone as shown in FIG. 2 according to step 199. First, the mobile phone is switched on to the test mode and a voltage suitable for a battery voltage calibration is set to the power supply 40 according to step 202. Then the control unit 26 of the measuring unit 20 sends a command to the mobile phone to start a battery voltage calibration according to step 206 and then the control unit is set to the listen mode. After receiving the command the mobile phone measures the battery voltage value in step 210, and after that automatically other battery related parameters, such as temperature or size indicators according to steps 210-216. When these test sequences are completed the mobile phone sends a ready message in step 219 to the control unit of the measuring unit. Thereafter the control unit commands the mobile phone to configure itself to a charger calibration mode and sets the power supply to a voltage suitable for the charger voltage calibration. After that the mobile phone performs the test according to steps 206-216. Next the control unit commands the power supply to send a constant current to the mobile phone according to steps 222-224 and 208. In step 206 the control unit commands the mobile phone to perform a charge current calibration according to steps 210-216. After the charge current calibration the mobile phone can automatically switch itself to a self-calibration mode according to step 222 to perform receiver (RX) baseband part related alignments. The mobile phone stores all the measurement results to the permanent memory either after a test sequence or a group of test sequences (step 214) so that after the whole test procedure is completed all the required test results are stored to the permanent memory of the mobile phone. When convenient, part of the test results may be sent from the mobile phone to the control unit in the middle of the test procedure in step 219 and the rest of the measurement results are sent after the test procedure is completed from the mobile phone to the control unit in step 226. Thereafter the mobile phone configures itself to the next calibration mode, e.g. a receiver calibration.

Next, according to this exemplary embodiment of the invention, a receiver (RX) calibration of a GSM or WCDMA mobile phone 10a, 10b, . . . 10n during production is presented. Let's again presume that a test software comprising a test procedure is programmed to the memory, preferably flash memory, of the mobile phone as shown in FIG. 2 according to step 199. For the receiver gain calibration, the RF unit 22 of the measurement unit 20 is controlled by the control unit 26 to the wanted frequency and power level and the modulation is set to a proper state, e.g. GMSK constant ‘0’. When the RF unit is ready the control unit sends a command to the mobile phone to start the receiver calibration according to step 206. Preferably, the mobile phone has already adjusted itself to this calibration mode without any further instruction from the control unit, immediately after it has completed the previous tests, e.g. receiver self tests. Typically, if three or four different gain values are calibrated it takes a few hundred microseconds. After that in step 210 the mobile phone automatically performs an Automatic Frequency Control (AFC) calibration. Then the mobile phone sends a ready message to the control unit in step 219 and the control unit configures the RF unit of the measurement unit to an AM calibration mode according to steps 222-224 and 208 and sends a corresponding command back to the mobile phone in step 206. The mobile phone first measures a RSSI level in the presence of a strong AM modulated signal in step 210 and if the measurement result is higher than a certain maximum allowed level it performs an AM suppression calibration according to steps 210-216. After the AM suppression measurement/calibration the RF unit is again set to the GMSK constant “0” modulation and to a low power level in steps 224 and 208 so that the receiver of the mobile phone uses the highest gain and a receiver signal to noise ratio (SNR) is measured according to steps 210-216. To optimize the testing time it is also possible that only samples from the SNR measurement are sent from the mobile phone to the control unit which then performs the SNR calculations. At the same time with the SNR measurement also I/Q amplitude and phase imbalance can be measured to improve the performance in an 8-PSK reception according to steps 210-216. Next the RF unit is configured to the receiver band filter calibration mode in steps 224 and 208 and all the required frequencies are swept synchronously in the mobile phone and in the measuring unit, i.e. without any further commands from the control unit. The synchronization between the mobile phone and control unit provides that setting changes in the RX band filter calibration do not need any communication on the bus between those two. Finally, the mobile phone stores all the measurement results to the permanent memory either after a test sequence or a group of test sequences (step 214) so that after the whole test procedure is completed all the required test results are stored to the permanent memory of the mobile phone. When convenient, part of the test results may be sent from the mobile phone to the control unit in the middle of the test procedure in step 219 and the rest of the measurement results are sent after the test procedure is completed from the mobile phone to the control unit in step 226. Then the whole test procedure, except for the automatic frequency control (AFC) calibration, is repeated in each frequency band of operation. After that the mobile phone reports the results (or the latest results) in step 226 to the control unit and configures itself to the next calibration mode, e.g. transmitter calibration.

Typical for alignments and tests of a transmitter part of a mobile phone under test, is that the control unit of the measuring unit commands the mobile phone to a specific state, e.g. to transmit power at a certain channel, and then measurements are executed in the measuring unit. Within the transmitter test procedure certain test parameters, such as alignment values for power levels, are reported from the control unit of the measuring unit back to the mobile phone under test. In transmitter tests the amount of data may also be relatively high which means that the measuring unit has to process nearly in real time certain parameters, such as spectrum data or phase errors.

Next, a transmitter (TX) calibration of a GSM or WCDMA mobile phone 10a, 10b, . . . 10n during production is presented. The TX power alignments can be done by sweeping a few power level control values, e.g. with a duty cycle of 50 percent, and by calculating correct power level control values on the basis of the measurement results. If the power amplifier includes several modes of operation, e.g. low and high power modes, the alignments should be repeated in each mode. Additionally, it is assumed that also the 8-PSK mode requires a separate alignment. All these alignments are completely controlled by the mobile phone itself according to steps 210-216, and thus no testing time is spent for control information transfer between the mobile phone and the control unit 26 of the measurement unit 20. After the required power alignments have been completed the power level control values are sent to the mobile phone according to step 225 and stored in the permanent memory of the mobile phone according to step 208. A transmitter I/Q amplitude and phase imbalance measurement can be performed in connection with a certain suitable power level during the power alignment. It is just required that the imbalances are measured by the RF unit and the values can be sent to the mobile phone at the same time with the power level control values in step 225. For I/Q DC offset calibrations a separate procedure is required; e.g., ten different DC offset values, both for I and Q DC offsets, are swept, and the minimum is then found by curve fitting to a parabolic equation.

After the TX alignments it must be checked that the transmitter calibration of a GSM or WCDMA mobile phone 10a, 10b, . . . 10n during production was successful. This is performed by checking that the alignments were successful and the mobile phone is working properly. These measurements include power measurements at certain selected power levels and channels, phase error and spectrum measurements. The phase error and spectrum can also be measured simultaneously because they are calculated from results of the same digital samples obtained at the same time. However, to see different parts of the spectrum, i.e. wide or narrow, several different sampling periods and sampling intervals might be needed. In practice, this may require that several TX bursts must be sent before all the required measurement results are available. The testing time depends on a number of channels and power levels to be tested and all the transmitter alignments and tests must be repeated in each frequency band of operation. Essential in the transmitter alignment and testing is that the mobile phone knows the whole test sequence beforehand (step 199). The mobile phone (as a measuring device) can concentrate on the aligning and testing according to steps 210-216. No control information flows between the mobile phone and the control unit and the control unit can fully concentrate on the measurement result handling according to step 230.

When convenient, part of the test results may be sent from the mobile phone to the control unit in the middle of the test procedure in step 219 and the rest of the measurement results are sent after the test procedure is completed from the mobile phone to the control unit in step 226. As an example of this partial result transfer feature from the mobile phone to the control unit is described the following: the measurement results of the energy management calibration and self tests can be sent in one go according to step 219, then the measurement results of the RX calibration in one go according to step 219, and finally the measurement results of the TX calibration in one go according to step 226. As mentioned earlier the sequential order of the tests can, however, be altered for practical reasons, so the description above should be mainly taken as an example. Also, it is emphasized that although the above description assumes sequential order in test execution, it is also possible to run some test cases in parallel, i.e. some of the energy management related calibrations in parallel with receiver calibrations. It is more or less dictated by implementation constraints (processor speed, SW complexity) how much tests can be run in parallel and what amount of test time improvements are achievable in this way.

The aligning and testing fixture depicted in FIG. 1a contains several modular test places for testing RF/BB modules of mobile phones under test. The number of modular test places is determined by a handling time of a single module and a mechanical flexibility. The system for aligning and testing during manufacturing according to the invention can be implemented in any production facility, factory and production line due to simplified test interface and instrumentation which means that less test station capacity is needed and floor area therefore.

In view of the foregoing description it will be evident to a person skilled in the art that various modifications may be made within the scope of the invention.

1. A method for aligning and testing during manufacturing at least one communication device operable in at least one frequency band by running a test procedure which is programmed in a memory of the communication device and in a memory of a control unit of a measurement unit, said test procedure comprising aligning and testing operations, the method comprising the steps of:
executing at least part of the test procedure by the communication device itself; and
minimizing information transfer between the control unit of the measuring device and the communication device during the test procedure.

2. A method according to claim 1, wherein executing the test procedure as a whole is completed in a period of time which depends on the operating rate of the communication device.

3. A method according to claim 1, wherein the test procedure is divided into a plurality of sequences, where each sequence is optimized firstly to minimize the information transfer between the communication device and the control unit of the measurement unit and secondly to maintain error check capabilities.

4. A method according to claim 3, wherein at least part of sequences of said plurality of sequences are executed simultaneously.

5. A method according to claim 1, wherein activating the communication device under test and alignment to a test mode is controlled by the control unit of the measurement unit and comprises the steps of:
switching a power supply on to supply power to the communication device; and
sending a command to the communication device to start said at least part of the test procedure.

6. A method according to claim 5, wherein activating the communication device under test and alignment to a test mode is controlled by the control unit of the measurement unit and comprises the further step of: switching a RF path on between the communication device and a RF unit of the measurement unit.

7. A method according to claim 5, wherein after sending a command to the communication device the control unit of the measuring unit is changed to a listen mode.

8. A method according to claim 1, wherein the method comprises the further step of: sending a message to the control unit of the measuring unit by the communication device after said at least part of the test procedure is completed.

9. A method according to claim 1, wherein the method comprises the further step of: storing test results of said at least part of the test procedure to the memory of the communication device.

10. A method according to claim 9, wherein the method comprises the further step of: sending the test results after the test procedure as a whole is completed from the memory of the communication device to the control unit of the measurement unit for further processing.

11. A method according to claim 10, wherein the method comprises the step of: further processing the test results of the communication device in the control unit of the measurement unit in parallel with executing a new test procedure of a new communication device under test and alignment.

12. A method according to claim 11, wherein the method comprises the step of: storing the test results of the communication device to a database by the control unit of the measurement unit in parallel with executing a new test procedure of a new communication device under test and alignment.

13. A method according to claim 11, wherein the method comprises the step of: outputting the test results of the communication device to a user interface by the control unit of the measurement unit in parallel with executing a new test procedure of a new communication device under test and alignment.

14. A method according to claim 1, wherein at least part of the test procedure is repeated in each frequency band of operation of the communication device.

15. A method according to claim 1, wherein the test procedure is part of a software program, which is programmed to the memory of the communication device before starting production aligning and testing.

16. A method according to claim 1, wherein the test procedure is a first module of a software program and the rest of a software program is a second module, where the first module is independent of the second module, and the first module is programmed to the memory of the communication device before starting the production aligning and testing, and the second module is programmed to the memory of the communication device after completing the production aligning and testing.

17. A method according to claim 16, wherein the first module is erased from the memory of the communication device after completing the production aligning and testing.

18. A method according to claim 16, wherein the memory of the communication device is a flash memory.

19. A method according to claim 1, wherein the communication device is a mobile phone.

20. A system for aligning and testing during manufacturing at least one communication device operable in at least one frequency band arranged to run a test procedure which is programmed in a memory of the communication device and in a memory of a control unit of a measurement unit, said test procedure comprising aligning and testing operations, the system comprising:
means for executing at least part of the test procedure by the communication device itself; and
means for minimizing information transfer between the control unit of the measuring device and the communication device during the test procedure.

21. A system according to claim 20, wherein the system is arranged to execute the test procedure as a whole in a period of time which depends on the operating rate of the communication device.

22. A system according to claim 20, wherein the test procedure is arranged to be divided into a plurality of sequences, where each sequence is optimized firstly to minimize the information transfer between the communication device and the control unit of the measurement unit and secondly to maintain error check capabilities.

23. A system according to claim 22, wherein at least part of sequences of said plurality of sequences are arranged to be executed simultaneously.

24. A system according to claim 22, wherein activating the communication device under test and alignment to a test mode is arranged to be controlled by the control unit of the measurement unit, the system comprising:
means for switching a power supply on to supply power to the communication device; and
means for sending a command to the communication device to start said at least part of the test procedure.

25. A system according to claim 24, wherein activating the communication device under test and alignment to a test mode is arranged to be controlled by the control unit of the measurement unit, the system comprising means for switching a RF path on between the communication device and a RF unit of the measurement unit.

26. A system according to claim 24, wherein after sending a command to the communication device the control unit of the measuring unit is arranged to be changed to a listen mode.

27. A system according to claim 20, wherein the system comprises means for sending a message to the control unit of the measuring unit by the communication device after said at least part of the test procedure is completed.

28. A system according to claim 20, wherein the system comprises means for storing test results of said at least part of the test procedure to the memory of the communication device.

29. A system according to claim 28, wherein the system comprises means for sending the test results after the test procedure as a whole is completed from the memory of the communication device to the control unit of the measurement unit for further processing.

30. A system according to claim 29, wherein the system comprises means for further processing the test results of the communication device in the control unit of the measurement unit in parallel with executing a new test procedure of a new communication device under test and alignment.

31. A system according to claim 30, wherein the system comprises means for storing the test results of the communication device to a database by the control unit of the measurement unit in parallel with executing a new test procedure of a new communication device under test and alignment.

32. A system according to claim 30, wherein the system comprises means for outputting the test results of the communication device to a user interface by the control unit of the measurement unit in parallel with executing a new test procedure of a new communication device under test and alignment.

33. A system according to claim 20, wherein at least part of the test procedure is arranged to be repeated in each frequency band of operation of the communication device.

34. A system according to claim 20, wherein the test procedure is arranged to be part of a software program, which is programmed to the memory of the communication device before starting production aligning and testing.

35. A system according to claim 20, wherein the test procedure is arranged to be a first module of a software program and the rest of a software program is arranged to be a second module, where the first module is independent of the second module, and the first module is programmed to the memory of the communication device before starting the production aligning and testing, and the second module is programmed to the memory of the communication device after completing the production aligning and testing.

36. A system according to claim 35, wherein the first module is arranged to be erased from the memory of the communication device after completing the production aligning and testing.

37. A system according to claim 35, wherein the memory of the communication device is a flash memory.

38. A system according to claim 20, wherein the communication device is a mobile phone.

39. An interface for aligning and testing during manufacturing at least one communication device operable in at least one frequency band to co-operate with an operating system of the communication device, by running a test procedure which is programmed in a memory of the communication device and in a memory of a controller of a measuring unit, said test procedure comprising aligning and testing operations, and said operating system comprising system operations, the interface comprising computer program code for executing at least part of the test procedure by the communication device itself and for minimizing information transfer between the control unit of the measuring unit and the communication device during the test procedure.

40. An interface according to claim 39, wherein the test procedure is arranged to be divided into a plurality of sequences, where each sequence is optimized firstly to minimize the information transfer between the communication device and the control unit of the measurement unit and secondly to maintain error check capabilities.
